(19) United States
(12) Patent Application Publication
(10) Pub. No.: US 2010/0124655 A1
(43) Pub. Date: May 20, 2010

(54) METHOD FOR FABRICATING CARBON NANOTUBE, WAFER FOR GROWING CARBON NANOTUBE, AND CARBON NANOTUBE DEVICE

(76) Inventors: LI-CHUN WANG, Longtan Shiang (TW); Han-Wen Kuo, Xizhi City (TW); Yuh Sung, Zhongli City (TW); Shiaw-Ruey Lin, Xizhi City (TW); Ming-Der Ger, Daxi Town (TW); Yih-Ming Liu, Zhongli City (TW); Wei-Ta Chang, Guishan Shiang (TW)

Correspondence Address: Dr. BANGER SHIA;Patent Office of Bang Shia, 102 Lindencrest Ct, Sugar Land, TX, 77479-5201, US

(21) Appl. No.: 12/273,418

(22) Filed: Nov. 18, 2008

(51) Int. Cl. B32B 3/26; D01F 9/12; C23C 16/26

(52) U.S. Cl. 428/319.1; 423/447.1; 427/249.1; 977/742

(57) ABSTRACT

The invention discloses a method for fabricating a carbon nanotube, and the method comprises the following steps: providing a substrate; forming a catalyst layer on the substrate; forming a porous capping layer on the catalyst layer to finish a wafer; forming the carbon nanotube on the wafer. By the porous capping layer, the well-aligned carbon nanotube can grow on the wafer through thermal CVD.

### BACKGROUND OF THE INVENTION

1. Field of the Invention

The invention relates to a method for fabricating a carbon nanotube, a wafer for growing a carbon nanotube, and a carbon nanotube device, and more particularly, to a method capable of fabricating a well-aligned carbon nanotube, a wafer for growing a well-aligned carbon nanotube, and a carbon nanotube device having well-aligned carbon nanotubes.

2. Description of the Prior Art

Carbon nanotube is a hollow tube in nm level, and has its unique mechanical properties, chemical properties, heat properties, and electrical properties. As to the mechanical properties, the carbon nanotube has features of light quality, high strength, high toughness, large surface area, and high aspect ratio. As to the chemical properties, the carbon nanotube has features of high chemical stability and difficult to corrode. As to the heat properties, the carbon nanotube has high heat stability and good heat conductivity. As to the electrical properties, the carbon nanotube can have features of conductor or semiconductor depending on its structure parameters. Additionally, the carbon nanotube can be used as a quantum device such as a quantum line. The unique physical and chemical properties can be used for various applications, thus a lot of resources are used to the research of the carbon nanotube and its applications.

Among all kinds of carbon nanotubes, the well-aligned carbon nanotube has good electrical/optical-electrical properties. For example, the well-aligned carbon nanotube can be used as a probe or an inner component of a transistor; the well-aligned carbon nanotube array can be used in an ultra-large-scale integration (ULSI) circuit or a field-emitting device.

In general carbon nanotube forming method, a solid, a gas, or a polymeric material comprising carbon element is used as a carbon source, and a metal such as iron, cobalt, nickel, rhodium, palladium, platinum or their alloy is used as a catalyst to assist the growth of carbon nanotube. The structure and property of the as grown carbon nanotube are affected by the type of the catalyst, thus several catalyst fabricating methods have already been developed in prior art to lower the fabrication cost of carbon nanotube and fabricate high quality carbon nanotubes.

For example, the above-mentioned method of catalyst fabricating can be one of the following methods.

(1) The binary metal sputtering method: molybdenum and iron/cobalt are used as sputtering targets and sputtered onto the wafer. Molybdenum can prevent the agglomeration of the catalyst metal (e.g., iron/cobalt) under high temperature, thus the diameter of the carbon nanotube can be effectively shrunken to benefit the growth of single wall carbon nanotube.

(2) The powder carrier method: a carrier (e.g., aluminum oxide, magnesium oxide, or zeolite) is mixed with the solution comprising transitional metal salts, and the steps of drying, high-temperature sintering, and reduction are performed to obtain catalysts of the transitional metal on the carrier.

(3) The multi-layer catalyst method: aluminum and other multi-layer metals are sputtered on the silicon substrate in order, because aluminum easily reacts with oxygen to form aluminum oxide in the heating process, the metal catalyst can distribute on the surface and hard to be agglomerated. Therefore, the growth of single wall carbon nanotube will benefit and the growth rate of carbon nanotube can also be increased.

(4) The buffer layer method: a buffer layer is sputtered on the silicon substrate and a catalyst layer is formed on the buffer layer. The buffer layer can prevent the formation of metal silicide generated by the catalyst and the silicon substrate under high temperature, wherein the metal silicide will obstruct the growth of carbon nanotube.

Conventionally, the thermal CVD method is used to grow the carbon nanotube. In the thermal CVD method, the carbon source is decomposed under high temperature, and the carbon source will be catalyzed by the catalyst particles on the substrate to deposit the carbon nanotube. With the catalyst fabricated by the above-mentioned fabricating methods, the diameter of the carbon nanotube or the growth rate of the carbon nanotube can be controlled by the thermal CVD method. Therefore, the carbon nanotube having good aspect ratio can be obtained.

However, the carbon nanotubes grown by the thermal CVD method have poor collimation. Therefore, these carbon nanotubes are not suitable for the application region that the well-aligned carbon nanotube is needed.

### SUMMARY OF THE INVENTION

Therefore, a scope of the invention is to provide a method for fabricating a carbon nanotube. The thermal CVD method can be used for forming well-aligned carbon nanotubes to solve the problems of the prior art.

According to an embodiment of the invention, the carbon nanotube fabricating method comprises the following steps of: providing a substrate, forming a catalyst layer on the substrate, forming a nanoporous capping layer on the catalyst layer to finish a wafer, and forming the carbon nanotube on the wafer. In this embodiment, the well-aligned carbon nanotubes can be grown on the wafer through thermal CVD.

Another scope of the invention is to provide a wafer for growing a carbon nanotube. The thermal CVD method can be used for forming well-aligned carbon nanotubes on the wafer.

According to an embodiment of the invention, the carbon nanotube growing wafer comprises a substrate, a catalyst layer, and a porous capping layer. The catalyst layer is formed on the substrate; the porous capping layer is formed on the catalyst layer. In this embodiment, when the wafer is under high temperature (i.e., in a process of the thermal CVD method), the porous capping layer can prevent the catalyst particles from agglomeration. Also, since the holes of the porous capping layer have collimation, the grown carbon nanotube has high length-diameter ratio and high collimation.

Another scope of the invention is to provide a carbon nanotube device. There are well-aligned carbon nanotubes on the carbon nanotube device.

According to an embodiment of the invention, the carbon nanotube device comprises a substrate, a catalyst layer, a porous capping layer, and a carbon nanotube. The catalyst layer is formed on the substrate; the porous capping layer is formed on the catalyst layer; the carbon nanotube can be formed on the porous capping layer through thermal CVD method. In this embodiment, when the thermal CVD method is processed, the porous capping layer can prevent the catalyst particles from agglomerating. Also, since the holes of the porous capping layer have good collimation, the grown carbon nanotube will have high length-diameter ratio and high collimation.

The advantage and spirit of the invention may be further understood by the following recitations together with the appended drawings.

### BRIEF DESCRIPTION OF THE APPENDED DRAWINGS

FIG. 1 shows a flowchart of the carbon nanotube fabricating method in the first embodiment according to the invention.

FIG. 2 shows a scheme diagram of the wafer for growing a carbon nanotube in the second embodiment according to the invention.

FIG. 3 shows a SEM diagram of the as grown carbon nanotube in the third embodiment according to the invention.

### DETAILED DESCRIPTION OF THE INVENTION

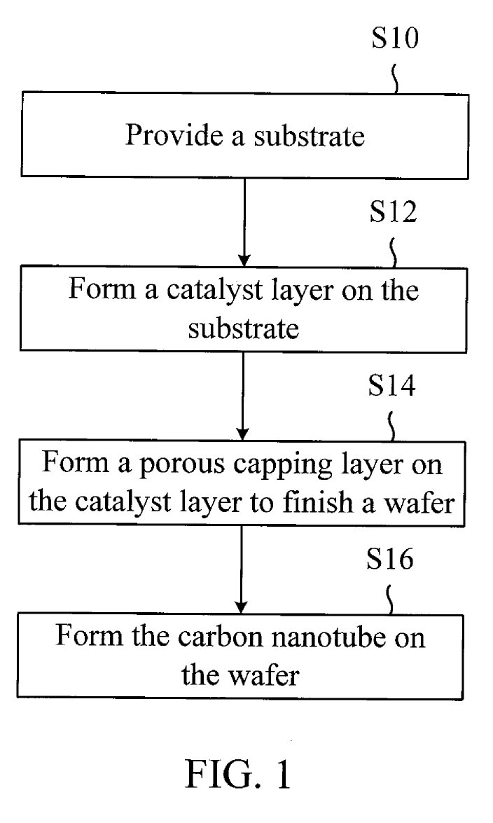

Please refer to FIG. 1. FIG. 1 shows a flowchart of the carbon nanotube fabricating method in the first embodiment according to the invention. As shown in FIG. 1, the carbon nanotube fabricating method comprises the following steps of: in step S10, providing a substrate; in step S12, forming a catalyst layer on the substrate; in step S14, forming a porous capping layer on the catalyst layer to finish a wafer; and, in step S16, forming the carbon nanotube on the wafer.

In this embodiment, the substrate in step S10 can be a silicon substrate, but not limited by this case. In fact, the catalyst layer in step S12 can be a metal, for example, iron, cobalt, nickel, rhodium, palladium, platinum, or their alloy, or a metal oxide of the above-mentioned metals, formed on the substrate by sputtering or other suitable process. However, the porous capping layer in step S14 can be an oxide (e.g., zinc oxide, calcium oxide, silicon oxide, aluminum oxide, magnesium oxide, yttrium oxide, lanthanum-aluminum-oxide, or any other suitable substance), a nitride (e.g., silicon nitride, aluminum nitride, or any other suitable substance), or a nitride-oxide (e.g., nitride-oxide-aluminum or any other suitable substance) formed on the catalyst layer by depositing or chemical immersing.

In this embodiment, the thickness of the catalyst layer can be, but not limited to, 1˜10 nm. However, the thickness of the porous capping layer can be 0.1˜10 nm.

In step S16, the thermal CVD method can be used for forming carbon nanotubes on the wafer. In practical applications, when a thermal CVD process is performed on the wafer, the porous capping layer can limit the size of the catalyst particles agglomerated from the heated catalyst layer, so that the diameter of grown carbon nanotube will not be larger due to the too large catalyst particle. Additionally, because the holes of the porous capping layer can have high collimation, the grown carbon nanotube can also have high collimation. However, because the catalyst layer is capped by the porous capping layer, the catalyst layer can be protected in the thermal CVD process to prevent the catalyst layer from being poisoned by the amorphous carbon. Furthermore, the growth rate of the carbon nanotube can be increased and the carbon nanotubes with broadly the same length can be obtained.

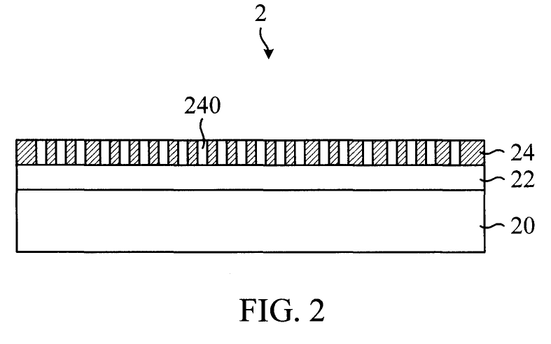

Please refer to FIG. 2. FIG. 2 shows a scheme diagram of the wafer 2 for growing a carbon nanotube in the second embodiment according to the invention. In practical applications, the wafer 2 can be fabricated by the method disclosed in the first embodiment of the invention. As shown in FIG. 2, the wafer 2 comprises a substrate 20, a catalyst layer 22, and a porous capping layer 24, wherein the catalyst layer 22 is formed on the substrate 20; the porous capping layer 24 is formed on the catalyst layer 22. The porous capping layer 24 has a plurality of holes 240 vertical to the growing direction of the carbon nanotubes, so that the carbon nanotubes can grow along the vertical direction of the holes 240 to make the carbon nanotubes have high collimation. It should be noticed that FIG. 2 is only a scheme diagram of the wafer 2. Thus, in practical applications, the number of the holes 240 depends on the material of the porous capping layer 24, not limited by this embodiment.

In this embodiment, the thermal CVD method used for fabricating the carbon nanotubes can comprise the following steps. Firstly, the wafer finished by step S14 is put into a high-temperature furnace, and the high-temperature furnace is vacuumed to the level of 10⁻² Torr. Then, the argon gas is inputted into the high-temperature furnace and the high-temperature furnace is then heated. When the temperature in the high-temperature furnace reaches the carbon nanotube growing temperature, the hydrogen gas is inputted into the high-temperature furnace to process the pre-treatment. After the pre-treatment is finished, the carbon gas source is inputted into the high-temperature furnace to grow the carbon nanotubes. After the growth of carbon nanotubes is finished, the argon gas will be inputted into the high-temperature furnace and the high-temperature furnace is cooled to reduce its temperature. It should be noticed that the carbon nanotubes formed in this embodiment can be taken from the wafer and used in other devices, or the carbon nanotubes can form a carbon nanotube device with the wafer itself.

In practical applications, the heating rate of the high-temperature furnace in the above-mentioned thermal CVD method can be 3˜30° C./min, wherein the better heating rate can be 5˜10° C./min; the growing temperature of carbon nanotube can be 650˜850° C., wherein the better growing temperature can be 750˜800° C. Additionally, the carbon gas source can be methane, ethane, propane, ethylene, acetylene, or the mixing gas of the above-mentioned gases. The gas flow can be 30˜600 sccm, wherein the better gas flow can be 80˜180 sccm.

It should be noticed that the above-mentioned parameters of the thermal CVD method are reference values, these parameters can be adjusted according to the structure of the carbon nanotube and the condition of the high-temperature furnace or any other thermal CVD apparatus. They are not limited by the case shown in this embodiment.

Please refer to Table 1. Table 1 illustrates the various kinds of the wafers fabricated by the method according to the invention and the types of the carbon nanotubes grown on these wafers.

In Table 1, the thermal CVD method is used to grow carbon nanotubes in all examples. The growing temperature and growing time are 800° C. and 10 minutes respectively. Additionally, acetylene is used as the carbon gas source, and iron-cobalt alloy of 1 nm thickness is used as the catalyst layer in all examples.

TABLE 1
Growing results of the carbon nanotubes with different buffer layers
and porous capping layers.

| | | Material of | | |
|---|---|---|---|---|
| | Material of | nanoporous | Appearance of | Length of carbon |
| Example | buffer layer | capping layer | carbon nanotube | nanotube (μm) |
| Comparison | Original oxide | | Crooked, | 5 |
| case 1 | layer | | thicker diameter | |
| Comparison | Magnesium | | Partly crooked, | 5 |
| case 2 | oxide | | partly straight | |
| Embodiment 1 | | Silicon oxide | Partly crooked, | 5 |
| | | | partly straight | |
| Embodiment 2 | | Aluminum | High collimation, | 10 |
| | | oxide | thicker diameter | |
| Embodiment 3 | | Magnesium | High collimation | 100 |
| | | oxide | | |

In the comparison case 1 and the comparison case 2, the buffer layer method in prior art is used to fabricate carbon nanotubes. The buffer layer is formed on the substrate; the catalyst layer is formed on the buffer layer. In the comparison case 1, an original oxide layer (i.e., the oxide layer formed on the substrate surface) is used as the buffer layer; in the comparison case 2, the magnesium oxide is used as the buffer layer.

As shown in Table 1, the carbon nanotubes of the comparison case 1 are crooked and have poor collimation. The average length of these carbon nanotubes is about 5 μm and these carbon nanotubes have thicker diameters. The carbon nanotubes of the comparison case 2 are partly crooked and partly straight, and the average length of them is also about 5 μm. However, a very thick layer of amorphous carbon film is formed on the surface of the carbon nanotube in the comparison case 2.

Silicon oxide, aluminum oxide, magnesium oxide are used as the nanoporous capping layer in embodiment 1, embodiment 2, and embodiment 3 respectively. As shown in Table 1, the carbon nanotubes of the embodiment 1 are partly crooked and partly straight, and the average length of them is also about 5 μm. No amorphous carbon film is formed on the surface of the carbon nanotube. The carbon nanotubes of the embodiment 2 are well-aligned and have high collimation. The average length of these carbon nanotubes is about 10 μm and these carbon nanotubes have thicker diameters. The carbon nanotubes of the embodiment 3 are well-aligned and have high collimation, and the average length of them can reach 100 μm.

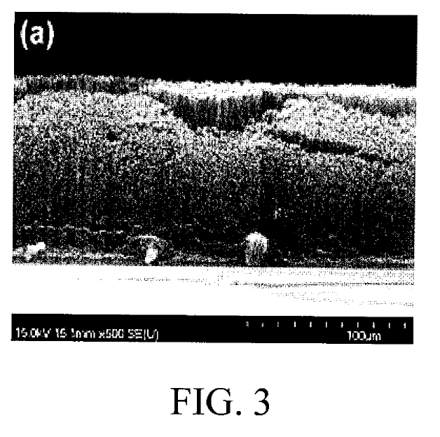

Please refer to FIG. 3. FIG. 3 shows a SEM diagram of the grown carbon nanotube film in the embodiment 3 of Table 1. As shown in FIG. 3, when magnesium oxide is used as the porous capping layer, the grown carbon nanotube has high collimation and larger length.

Compared with the prior art, the carbon nanotube fabricating method disclosed by the invention forms a porous capping layer on a catalyst layer to finish a wafer for growing carbon nanotubes, performs thermal CVD on the wafer to grow carbon nanotubes, and even forms carbon nanotube devices. When the carbon nanotubes are formed on the above-mentioned wafer, the porous capping layer will protect the catalyst layer from being poisoned by the amorphous carbon and the growing rate of carbon nanotube will increase accordingly. The holes of the porous capping layer can limit the size of the catalyst particle to further shrink the diameter of the carbon nanotube. However, because the holes of the porous capping layer can have high collimation, the grown carbon nanotubes will also have high collimation.

With the recitations of the preferred embodiment above, the features and spirits of the invention will be hopefully well described. However, the scope of the invention is not restricted by the preferred embodiment disclosed above. The objective is that all alternative and equivalent arrangements are hopefully covered in the scope of the appended claims of the invention. Accordingly, the above disclosure should be construed as limited only by the metes and bounds of the appended claims.

What is claimed is:

1. A method for fabricating a carbon nanotube, comprising the steps of:
providing a substrate;
forming a catalyst layer on the substrate;
forming a porous capping layer on the catalyst layer to finish a wafer; and
forming the carbon nanotube on the wafer.

2. The method of claim 1 wherein the catalyst layer is composed of a metal or composed of an oxide of the metal.

3. The method of claim 2, wherein the metal comprises at least one selected from the group of iron, cobalt, nickel, rhodium, palladium, platinum, and their alloys.

4. The method of claim 1, wherein the nanoporous capping layer is composed of at least one material selected from the group of zinc oxide, calcium oxide, silicon nitride, aluminum nitride, nitride-oxide-aluminum, silicon oxide, aluminum oxide, magnesium oxide, yttrium oxide, and lanthanum-aluminum-oxide.

5. The method of claim 1, wherein the porous capping layer is formed on the catalyst layer by depositing or chemical immersing.

6. The method of claim 1, wherein the carbon nanotube is formed on the wafer through thermal CVD.

7. A wafer for growing a carbon nanotube, comprising:
a substrate;
a catalyst layer formed on the substrate; and
a porous capping layer formed on the catalyst layer;
wherein the carbon nanotube is grown on the porous capping layer.

8. The wafer of claim 7, wherein the catalyst layer is composed of a metal or composed of an oxide of the metal.

9. The wafer of claim 8, wherein the metal comprises at least one selected from the group of iron, cobalt, nickel, rhodium, palladium, platinum, and their alloys.

10. The wafer of claim 7, wherein the porous capping layer is composed of at least one material selected from the group of zinc oxide, calcium oxide, silicon nitride, aluminum nitride, nitride-oxide-aluminum, silicon oxide, aluminum oxide, magnesium oxide, yttrium oxide, and lanthanum-aluminum-oxide.

11. The wafer of claim 7, wherein the porous capping layer is set on the catalyst layer by depositing or chemical immersing.

12. The wafer of claim 7, wherein the carbon nanotube is grown on the wafer through thermal CVD.

13. A carbon nanotube device, comprising:
a substrate;
a catalyst layer formed on the substrate;
a porous capping layer formed on the catalyst layer; and
a carbon nanotube formed on the porous capping layer.

14. The carbon nanotube device of claim 13, wherein the catalyst layer is composed of a metal or composed of an oxide of the metal.

15. The carbon nanotube device of claim 14, wherein the metal comprises at least one selected from the group of iron, cobalt, nickel, rhodium, palladium, platinum, and their alloys.

16. The carbon nanotube device of claim 13, wherein the porous capping layer is composed of at least one material selected from the group of zinc oxide, calcium oxide, silicon nitride, aluminum nitride, nitride-oxide-aluminum, silicon oxide, aluminum oxide, magnesium oxide, yttrium oxide, and lanthanum-aluminum-oxide.

17. The carbon nanotube device of claim 13, wherein the porous capping layer is set on the catalyst layer by depositing or chemical immersing.

18. The carbon nanotube device of claim 13, wherein the carbon nanotube is formed on the porous capping layer through thermal CVD.
